(19) United States
(12) Patent Application Publication
(10) Pub. No.: US 2026/0119756 A1
(43) Pub. Date: Apr. 30, 2026

(54) Method for Transistor Layout Generation Using Graph Neural Network Recursive Model

(71) Applicant: GenChip.AI Inc., Sunnyvale, CA (US)

(72) Inventors: Sreekar Bathula, San Jose, CA (US); Eric Panning, Portland, OR (US)

(21) Appl. No.: 19/376,791

(22) Filed: Oct. 31, 2025

Related U.S. Application Data
(60) Provisional application No. 63/714,797, filed on Oct. 31, 2024.
(60) Provisional application No. 63/714,754, filed on Oct. 31, 2024.
(60) Provisional application No. 63/714,761, filed on Oct. 31, 2024.
(60) Provisional application No. 63/714,793, filed on Oct. 31, 2024.
(60) Provisional application No. 63/714,796, filed on Oct. 31, 2024.
(60) Provisional application No. 63/714,773, filed on Oct. 31, 2024.

(51) Int. Cl. G06F 30/27; G06F 30/392

(52) U.S. Cl. CPC G06F 30/27; G06F 30/392

(57) ABSTRACT

A method for automating semiconductor design using a graph neural network (GNN) and a generative adversarial network (GAN) for layout generation. The method includes receiving a netlist of an integrated circuit from an electronic design automation tool, identifying transistors as nodes, and creating a GNN that connects these nodes. The method generates node embeddings for the GNN, orders the node embeddings, and performs parasitic extraction between nodes to generate parasitic extraction values. The GAN evaluates and modifies the order of node embeddings to optimize design parameters such as performance and power. The method then generates a physical layout design based on the optimized order of node embeddings and outputs the design to a memory store. The process can iterate to further refine the layout, ensuring it meets specified design criteria including area and cost.

### CROSS-REFERENCE TO RELATED APPLICATIONS

This application claims the benefit of and priority to U.S. Provisional Patent Application Ser. No. 63/714,754 entitled “Method for Estimating Parasitic Capacitance Using Spatial Localization,” 63/714,761 entitled “Method and System for Estimating Parasitic Capacitance Using Localized Weighting and Federated Learning Model,” 63/714,793 entitled “Method for Transistor Order Placement Using Graph Neural Network Recursive Model,” 63/714,797 entitled “Method for Transistor Layout Generation Using Graph Neural Network Recursive Model,” 63/714,796 entitled “Method for Transistor Layout Design Checking Using Reinforcement Learning,” and 63/714,773 entitled “Method For Transistor Layout Design Using 3D Model Representation in Latent Space,” all of which were filed on Oct. 31, 2024 and which applications are expressly incorporated herein by reference in their entirety.

### BACKGROUND OF THE INVENTION

The present disclosure generally relates to electronic design automation for the design and manufacture of integrated circuits and microelectronics.

Electronic design automation (EDA) includes software tools for designing electronic systems such as integrated circuits. With semiconductor chips having billions of components or more, computer-aided tools are essential for logical design, physical design, and manufacturing processes. Integrated circuit design includes many steps, typically beginning with a system specification. After system specification, several logical design steps can be completed based on that specification including register transfer level design, functional verification, timing simulation, and netlist generation. After logical design, physical design steps can be executed to generate a physical layout of the integrated circuit. There are many physical design steps including partitioning, floor planning, placement, clock tree synthesis, and signal routing, among others. After a physical layout is verified, then an integrated circuit can be fabricated using the physical layout generated from EDA tools.

EDA tools are helpful to optimize the production process for semiconductor devices, such as integrated circuits. Such optimization involves designing semiconductor layouts and evaluating properties of the designs. Important properties assessed include resistance and capacitance, which are instrumental in deriving estimates for Power, Performance, Area, and Cost (PPAC) of a semiconductor device. The accurate estimation of these properties can significantly influence cost savings. Various tools are employed in this process to perform detailed 3D assessments of the designs, enabling precise point-to-point calculations of resistance and capacitance. During the physical design process of an integrated circuit, a significant variable to generating an acceptable design that meets logical constraints and system specifications is parasitic capacitance. Parasitic capacitance is the unwanted, yet unavoidable, capacitance that exists between conductive parts of an electronic circuit. Parasitic capacitance can cause the behavior of chip components to depart from ideal performance. The calculation of resistance and capacitance thus plays an important role in determining power and performance values.

Physical layout design for integrated circuits is often complicated, challenging, and time consuming. A given logical design can identify the logical circuits and transistors to be included in a particular design, but then identifying a physical placement layout of transistors—that meets device specifications—is challenging because of the millions or more different layouts possible, each with respective advantages and disadvantages.

### SUMMARY OF THE INVENTION

Maintaining continuous, accurate, and precise operation of semiconductor manufacturing tools is essential for maximizing device yield. These tools, however, often require extensive processing time due to the rigorous calculations needed to ensure that devices are manufactured correctly. These calculations provide important feedback for refining initial device designs. Delays and yield losses can significantly decrease productivity and increase the depreciation costs of processing tools. Furthermore, these tools impact the productivity of engineers and limit opportunities for optimizing designs.

Conventional tools that perform parasitic extraction (PEX) calculations take an initial layout as input, actuate the process to create the complete semiconductor device, and then calculate the resistance and capacitance values based on the process and design. These calculations are then analyzed to correct the layout. This iterative process continues until the desired value set is achieved. This iterative process is very time consuming, which can add significant costs and/or delays to circuit design.

Techniques herein provide methods and systems to improve electronic design accuracy and time. Techniques herein include methods of generating transistor layout in a physical design to best meet design specifications by using a network trained to extract the capacitance and resistance values of the layout. Networks used herein can include graph neural networks, recurrent neural nets, transformer architectures, and incorporate other technologies such as machine learning models for estimating parasitic capacitance and other design values.

A system of one or more computers can be configured to perform particular operations or actions by virtue of having software, firmware, hardware, or a combination of them installed on the system that in operation cause the system to perform the actions. One or more computer programs can be configured to perform particular operations or actions by virtue of including instructions that, when executed by data processing apparatus, cause the apparatus to perform the actions. One general aspect includes a method for automating semiconductor design. The method includes receiving a netlist of an integrated circuit from an electronic design automation tool. The netlist includes a description of electronic components including transistors (transistor devices) and electrical connectivity. The method also includes identifying transistors from the netlist as nodes for representing each transistor as a node in a network. The method also includes creating, by a processing device, a graph neural network that connects nodes identified from the netlist, each node in the graph neural network represents parasitic extraction data contact points of transistors. The method also includes generating, by the processing device, node embeddings for the graph neural network using a generative adversarial network (GAN) or a separate graph neural network as well as generating an initial order of node embeddings. The method also includes evaluating, by the processing device, the initial order of node embeddings using the generative adversarial network and parasitic extraction data, the generative adversarial network creating a modified order of node embeddings that is closer to predetermined design parameter values of at least performance and power compared to the initial order of node embeddings. The method also includes generating, by the processing device, a physical layout design based on the modified order of the node embeddings. The method also includes outputting, by the processing device, the physical layout design to a memory store. Other embodiments of this aspect include corresponding computer systems, apparatus, and computer programs recorded on one or more computer storage devices, each configured to perform the actions of the methods.

### BRIEF DESCRIPTION OF DRAWINGS

This disclosure will be understood more fully from the detailed description below and from the accompanying figures of embodiments of the disclosure. The figures are used to facilitate understanding of embodiments of the disclosure and do not limit the scope of the disclosure to these specific embodiments. The figures are not necessarily drawn to scale.

FIG. 1 is a schematic and flow diagram of systems herein for efficient parasitic extraction and training.

FIG. 2 shows a system architecture for embodiments used herein.

FIG. 3 is a diagram of example subsystems used herein.

FIG. 4 is a flow diagram for transistor order placement using a graph neural network.

FIG. 5 is a flow chart of example embodiments herein.

FIG. 6 depicts a representative diagram of an example computer system in which embodiments of the present disclosure may operate.

### DETAILED DESCRIPTION

Techniques herein include methods of placing transistors in a physical design to best meet design specifications by using a network trained to extract the capacitance and resistance values of the layout. Networks used herein can include graph neural networks, recurrent neural nets, and transformers. A related disclosure of inventors herein includes a machine learning model to approximate these calculations and process the calculations within seconds using inference-based estimation techniques. This is a localization and weighting model. These machine learning models can provide more than 99% accuracy, and with a latency of seconds to get PPAC values for evaluation.

The localization and weighting model can use these calculations to construct another deep learning model that can output an acceptable layout (improved layout) with the transistors taken as an input. The output of the modes is an optimized layout design for semiconductor devices

This approach treats or represents a layout as an embedding. This embedding is generated by using the layer properties as input data that is trained on an encoder-decoder network. This input data is split into a dimension of W×H×L where W and H are the fixed image size, and L is a number of layers. Each Layer W×H has ones in the image if that layer is existing in the data, otherwise it is a zero. The result from this architecture herein generates embedding of a layout that produces desired PPAC values.

More specifically, techniques herein include creating embeddings or embedded values using a recurrent graph neural network (GNN) and then passing them through a transformer-like architecture to obtain the correct ordering of these embeddings. The correct ordering herein is an ordering that is improved or optimized or sufficient to meet specified design parameters. Data to train the recurrent GNN model is based on a model for localized weighting and federated learning. Such a model is described in U.S. patent application Ser. No. 19/376,681 titled Method and System for Estimating Parasitic Capacitance Using Localized Weighting and Federated Learning Model, filed concurrently herewith, the contents of which are incorporated herein by reference in their entirety. The methods described in the localized weighting model provide efficiency in estimating parasitics by excluding some physical nodes from calculation (limiting included nodes) and spatially weighting physical nodes used in calculations to estimate parasitic capacitance of various layouts.

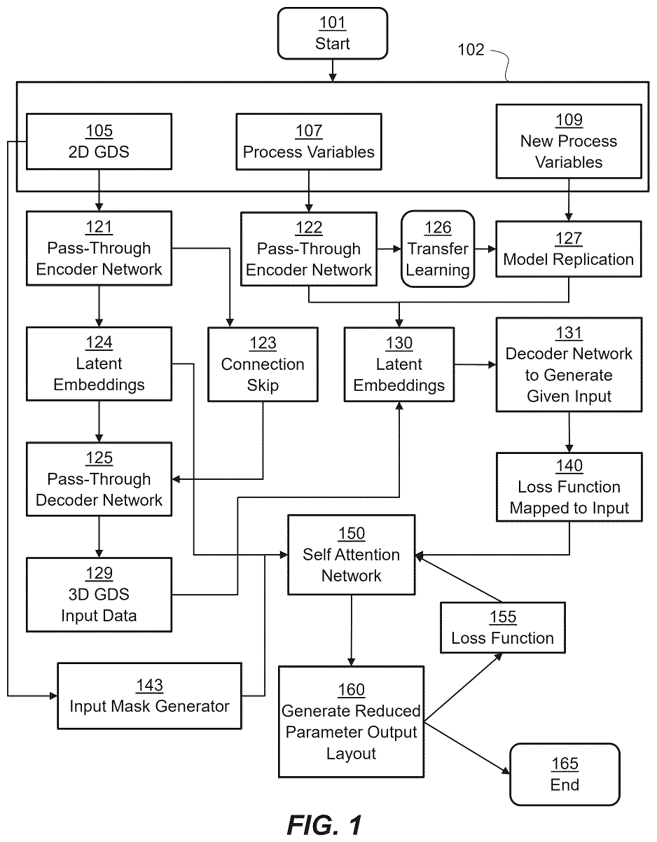

Referring now to FIG. 1, a schematic system diagram and process flow illustrates how various embodiments herein can be combined for improved efficiency in estimating parasitic capacitance in semiconductor device layouts. At step 101, the process starts and initiates a sequence for estimating parasitic capacitance using a neural-network-based model that may include federated learning. Inputs 102 serve as the foundational entry point for the system and include three primary data sources: (1) the 2D GDS input 105 (layout data), (2) the process variables 107, and (3) the new process variables 109.

The 2D GDS Input 105 provides a two-dimensional representation of the semiconductor layout. This 2D GDS (Graphic Data System) input can include polygon shapes, layer assignments, feature sizes, spacings, and metal widths. This geometric data is parsed into an internal representation such as a planar graph with nodes representing conductor edges or via endpoints for subsequent feature extraction and encoding. The process variables 107 define the operating conditions and fabrication parameters of the semiconductor device, including layer dielectric constants, ambient temperature, supply voltage, feature size scaling, metal resistivity, doping concentration, oxide thickness, and interlayer capacitance multipliers. These variables directly influence the electromagnetic behaviour of the layout and are beneficial to accurate capacitance prediction. The new process variables 109 introduce dynamic parameters that may emerge during model usage or retraining, such as process drift, changes in fabrication recipes, variations in ambient conditions, or user-specified constraints. These are incorporated into the system via input streams or metadata, enabling the model to adapt to evolving process conditions and maintain predictive accuracy.

The pass-through encoder network 121 processes the 2D GDS input 105, transforming the raw geometric/layout data into a latent space representation. In one embodiment, this encoder is a graph neural network (GNN) that takes nodes (e.g. polygon edge, via, metal segment) and edges (adjacency, proximity, nets) and computes node embeddings using several layers (e.g., 35 message passing rounds), with non-linear activations (Rectified Linear Unit, Leaky Rectified Linear Unit) and batch normalization. The network may embed both geometric features (length, width, density) and context features (nearness to other nets, dielectric layer above/below, etc.). Similarly, the pass-through encoder network 122 processes the process variables 107 (and new process variables 109), mapping them to a latent vector or embedding via a fully connected (dense) neural network (multi-layer perceptron), normalizing input variables, optionally applying embedding layers for categorical variables (e.g., material type), and combining into a fixed-size vector. The connection skip 123 provides skip connections from earlier layers of encoders (or between corresponding encoder/decoder stages), enabling bypass of some layers to allow residual paths, reduce vanishing gradient problems, and help preserve fine structural detail from the layout. For example, the encoder's first and/or second layers may be directly connected to corresponding decoder layers.

The latent embedding 124 is the result of combining the outputs of the layout encoder (pass-through encoder network 121) and process-variables encoder (pass-through encoder network 122), for example, via concatenation or elementwise addition, optionally followed by projection (dense layers) and optional normalization. This embedding captures the joint influence of geometry, material properties, and layout context in a compact numerical form (e.g. a vector of dimension 128-1024 depending on a given embodiment). The pass-through decoder network 125 reconstructs from the latent embedding 124 an internal representation that is aligned with the input layout specification for purposes such as predicting parasitic capacitances or producing intermediate layout predictions. This decoder may mirror the encoder architecture (e.g., reverse message passing, graph un-pooling) and then map back to per-node or per-edge values: e.g., predicted capacitance between node pairs, or mapping back to GDS shapes or layout features.

The transfer learning module 126 allows the model trained on one or more Process Design Kits (PDKs), which include design rules, device models, and process parameters that define the foundry's manufacturing capabilities to be adapted to new PDKs. In one embodiment, the model's encoder/decoder weights are pretrained on a large dataset of layouts and process variables from multiple foundries, then fine-tuned on a smaller dataset for the target PDK. In some embodiments, input can include process rules that define a foundry process capability. Hyperparameters (for example, learning rates and regularization) are chosen to avoid overfitting. The model replication 127 component duplicates the trained/fine-tuned model, allowing parallel or distributed inference or evaluation over multiple layout instances or multiple process variable sets. For example, once the model is trained, multiple replicas can run inference on different candidate layouts simultaneously to speed up design evaluation.

The 3D GDS input data 129 provides an optional but more detailed input form: three-dimensional layout data including height/thickness of layers, via stacks, interlayer dielectrics, volumetric features. Such 3D input may come from 3D layout tools or be inferred from stacking of 2D layers plus material thickness. This latent embedding 130 captures features of the 3D GDS input data 129, this 3D data is processed to yield latent embeddings 130 by a 3D encoder network (e.g., a volumetric graph or tensor network) that captures interlayer coupling, parasitic effects in the vertical direction, and thus improves accuracy of predicted capacitances (especially coupling capacitance between layers).

The decoder network 131 reconstructs the latent embedding 130 (from the 3D encoder) into predicted layout or capacitance outputs aligned with the original 3D specification: e.g., node-to-node capacitance, interlayer coupling values, or predicted parasitic values for 3D features. The input mask generator 143 reduces dimensionality by selecting a subset of nodes/features or edges considered for detailed estimation. For example, selections can include masking out features below some width threshold, or far from nets of interest, or selecting high-impact nets based on distance, adjacency, or previous estimates. Masking may also be based on a learned criterion (attention scores, or a small network that predicts node importance). This helps reduce computational cost without sacrificing much accuracy.

The loss function 140 evaluates the accuracy of the model's predictions compared to rigorous TCAD (Technology Computer-Aided Design) simulation parasitic extraction (PEX) or simulation data. Loss terms may include mean squared error (MSE) of capacitance values per node pair, percent error, or other domain-specific error metrics. Regularization terms (L2 weight decay, possible edge connectivity penalties) may be included. The “mapped to input” phrasing refers to mapping predicted values back to the same layout or nodes used in input so that error is computed over corresponding elements.

The self-attention network 150 identifies relationships or interactions among features. For example, the self-attention network 150 can allow each node in the latent graph embedding to attend to neighboring nodes, nets, or material layers to modulate how much influence each neighbor has on local parasitic behavior. In one embodiment, this is implemented similarly to transformer-style attention over graph nodes, or over spatial patches of layout, where attention weights are learned. The loss function 155 further refines the model's predictions by applying auxiliary or combined objectives, for example consistency loss across multiple PDKs, smoothness of capacitance across spatial transitions, or penalty for embedding divergence. Together, loss function 140 and loss function 155 ensure both raw prediction accuracy and generalization.

Step 160 generates an output layout having reduced parameters. That is, from the decoder outputs (whether from 2D only, 3D, or combined), the method produces a layout (or layout metadata) that retains or highlights only parameters or features considered most relevant to parasitic performance. For example, output can be constrained to a fixed percentage (for example, the top 10% to 20%) of nets or node pairs with highest predicted parasitic capacitance, or only features within a threshold distance to critical nets; or limiting outputs to nodes/features above a certain size or width. This reduced parameter layout may omit or suppress less important features in downstream PEX or design checks to speed up design iterations. At step 165, the process ends. This process may be repeated in cycles (retraining, new data) for further refinement, or invoked for each new layout or new process variable set.

Embodiments herein can include a data generation model for transistor embeddings. The data generation model disclosed herein includes several process steps. One step is node generation. Nodes generated represent center points of transistors (for example the centroid of source, gate, drain geometry), and can include corresponding resistance, capacitance (RC) values between any two transistors (e.g., the coupling capacitance or RC delay) derived from known physical extraction tools or simulations. Another step is PEX data inversion. Training data can be obtained by performing inverse calculations on parasitic extraction (PEX) data (from EDA tools) to produce features that best explain observed parasitics, such as solving for unknown adjacency capacitance contributions, or back-calculating layout densities. Another step is netlist variations. Such a data generation process includes training on the same set of netlists, but with various placement orders (changing order in which transistors are placed, or variations in physical layout) to learn sensitivity of latent embeddings to layout ordering, adjacency, and density. Note that the input mask to obtain nodes at center point of each transistor can be an input mask for transistors or other filter (for example filtering based on transistor size, or only high-drive transistors).

The data generation model further includes labeling of training samples with corresponding PPAC metrics (Performance, Power, Area, Cost). For each training layout (or netlist+placement+process-variable combination), these PPAC values are computed (or extracted via simulation or via known models). These PPAC metrics are associated with the training instance so that the model can learn to predict or optimize for them.

One embodiment herein uses the generated data to train a recurrent GNN (Graph Neural Network), which creates node embeddings based on the input mask data. The recurrent GNN forms nodes and edges (edges may include adjacency, net connectivity, mutual capacitance potential), and train via backpropagation using the losses defined (from loss function 140 and loss function 155), to obtain the node embeddings. For example, recurrent GNN can include that node embeddings are updated iteratively. And then in each iteration, messages passed among neighbors and embeddings updated, for example over 3-10 rounds, until convergence or a fixed number of steps.

To achieve a model that processes the netlist as input and determines the optimal order of transistor placement (or ordering), there are process steps that can be executed. One step is designing embeddings. Embeddings are designed for each transistor device, where each transistor described by its source, gate, and drain terminals, is treated as a single embedding vector. Features in that embedding vector may include transistor geometrical parameters (width, length, channel area), electrical parameters (gate oxide thickness, threshold voltage), netlist connectivity (which nets it's connected to, fan-in/fan-out), proximity to other transistors, et cetera. Each transistor device embedding can be processed through a recurrent (or recursive) neural network (or the GNN) to obtain modified embeddings reflecting layout effects.

In the embodiment involving transformer training, the modified embeddings (from recurrent GNN) are passed through a transformer architecture (multi-headed attention, positional encodings corresponding to netlist order or spatial location) to produce a predicted ordering of transistors or features. The transformer may have a stack of layers (for example 412 transformer encoder layers), each consisting of self-attention followed by feedforward layers, layer normalizations, and dropout for regularization. The transformer is trained to minimize a loss between predicted ordering and a rigorous simulation's best transistor placement order (from PPAC ranking). The training dataset includes many netlist/layout/order combinations so that model generalizes.

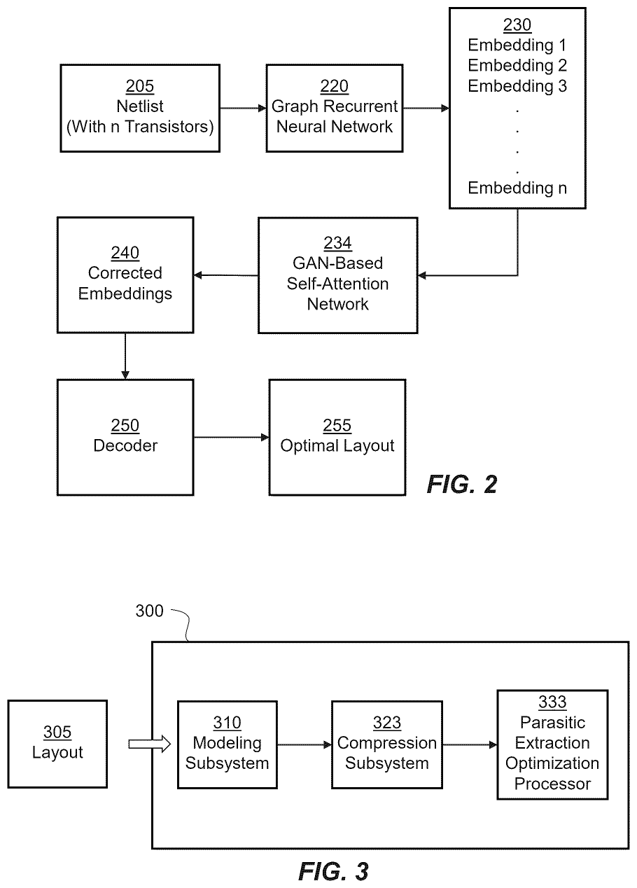

This process ensures that the model accurately determines a placement of transistors closest to specified PPAC values. FIG. 2 illustrates a system architecture of example embodiments herein.

FIG. 2 illustrates a system architecture for transistor layout generation using a graph neural network (GNN) and a self-attention network. The system begins by receiving a netlist 205, which includes a set of transistors or a description of the number of transistors in the design. The netlist 205 acts as the initial input to the system, representing the transistors and their interconnections. A graph recurrent neural network 220 is then employed to process this netlist 205, wherein each transistor (or node) is represented in the form of a graph structure. The graph recurrent neural network 220 generates embeddings 230 for each transistor, effectively capturing the characteristics and relationships between transistors. These embeddings 230 are high-dimensional vectors that represent the transistors in a manner that allows further analysis and optimization.

The embeddings 230 produced by the graph recurrent neural network 220 are then passed to a self-attention network 234. This self-attention network 234 processes the embeddings 230 to determine the relative importance of each embedding, allowing the network to focus on the most relevant features for optimizing the layout. It computes the interactions and dependencies between embeddings by evaluating how each embedding relates to others in the set. In this context, a GAN-based self-attention mechanism is used to refine the embeddings. Specifically, the system uses a Generative Adversarial Network (GAN) to optimize the embeddings 230 iteratively. During this process, the embeddings undergo corrections and adjustments through adversarial training, ultimately leading to corrected embeddings 240. The corrected embeddings are a refined representation that enables more accurate optimization of the physical layout in subsequent stages.

A decoder 250 is employed to convert the corrected embeddings 240 into a physical layout, referred to as the optimal layout 255. The decoder interprets the high-dimensional embeddings and generates a physical layout for the transistors, which includes both metal and transistor placements. This decoder uses the corrected embeddings to ensure that the final layout meets the design goals, such as minimizing the power, performance, area, and cost (PPAC) trade-offs. The optimal layout 255 is a physical design that satisfies the specified design parameters, resulting in a transistor layout that efficiently meets the desired performance, power consumption, area usage, and cost metrics.

FIG. 3 is a simplified schematic showing embodiments using a subsystem 300 (or other subsystem of a larger system). The compression subsystem 323 and its associated processors can be an improved computing subsystem and/or algorithm that performs data reduction, feature selection, or simplification of layout or parasitic extraction data, so that the parasitic capacitance optimization processor 333 has less data to process. The speed improvement arises because the compression subsystem 323 reduces input dimensionality, filters less relevant features, or limits the amount of data passed on, thereby reducing computational load, memory usage, and possibly also reducing model inference time.

The compression subsystem 323 receives input from modeling subsystem 310, which generates or proposes candidate physical layouts or logical layouts. These layouts may come from layout design tools, netlist-to-placement/placement-to-layout steps, or from user inputs. The layout input is denoted layout 305, which contains geometric layout information (layers, shapes, widths, spacings), connectivity (nets), design rules, and optionally process or material metadata.

Within subsystem 300, modeling subsystem 310 may also simulate or approximate parasitic effects or generate features useful for downstream modules. For example, modeling subsystem 310 may compute or extract preliminary features such as net lengths, metal widths, spacing, layer thickness, via count, overlap regions, and adjacency (nearby conductors) information. These features become candidates for compression. Some embodiments may integrate subsystem 300 as part of a larger system that includes layout generation, transistor ordering, PPAC (Performance-Power-Area-Cost) optimization, and final parasitic extraction. In such a system, subsystem 300 acts as an upstream filter, reducing the computational burden on downstream modules, enabling faster iteration cycles in the design verification flow.

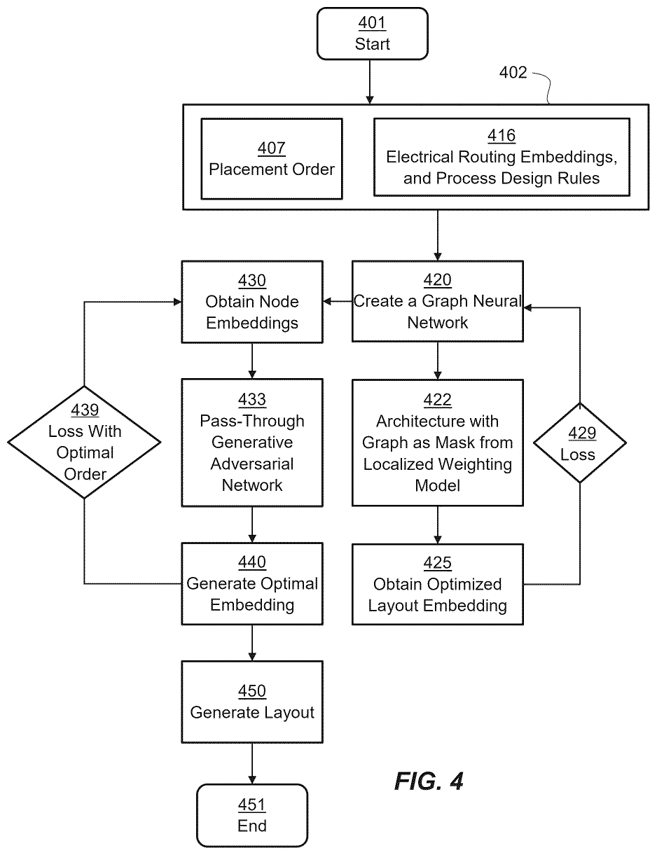

FIG. 4 illustrates a flow diagram of a recursive Graph Neural Network (GNN) model used to estimate a score or ranking for transistor placement and layout, particularly for parasitic extraction and training. The process begins at Step 401, which initializes the system. Step 402 represents the input stage, which can include two separate inputs. Placement order 407 is a first input, and input 416 is a second input that includes electrical routing embeddings with process design rules. Placement order 407 can include a specification of the sequence and relative positioning of transistors within a layout, which is beneficial to translate a circuit's logical design or description into a physical layout to be fabricated. Such a placement order can be generated using a graph neural network, such as described in U.S. application Ser. No. 19/376,746 titled Method for Transistor Order Placement Using Graph Neural Network Recursive Model, file concurrently herewith, which is incorporated herein by reference in its entirety.

Input 416 can include detailed information derived from the circuit's netlist indicating how electrical connections should be embedded within the layout, along with the process design rules that govern their implementation. The netlist acts as a connectivity map, specifying which components need to be linked, and the routing embeddings translate this logical connectivity into a physical representation that enables manufacturing. Process design rules, on the other hand, impose constraints such as spacing, layer dimensions, and alignment to ensure the layout is both reliable and compliant with fabrication standards.

The system separates individual transistors from the netlist. Each transistor (transistor device) typically has three terminals of source, drain, and gate. This parsing step enables the identification of discrete transistor instances for further processing. Each transistor is treated as a node, and a fully connected graph is constructed. This graph captures all possible interactions between transistors, forming a dense connectivity structure that serves as the input for the GNN.

Step 420 involves constructing the Graph Neural Network using the fully connected graph. The GNN is designed to learn spatial and electrical relationships among transistors. In Step 422, the architecture applies a localized weighting model using the graph as a mask. This allows the model to emphasize certain node relationships over others, improving the relevance and accuracy of the learned embeddings.

Step 425 obtains an optimized layout embedding for initial node embeddings. Step 429 evaluates the loss or uses a loss function to refine node embeddings based on ground truth data. This step involves calculating the loss function to assess the accuracy and performance of the GNN model. An input loss target or threshold may be used to determine whether the current loss is within acceptable limits. If the loss exceeds the target, the process may iterate to refine the model, which can include creating a new graph neural network or a modified graph neural network.

Step 430 finalizes the node embeddings, which are then passed through a Generative Adversarial Network (GAN) in Step 433. The GAN includes a generator that proposes new layout configurations and a discriminator that evaluates their quality. Unlike traditional GANs used for media generation (realistic images, video or text), this GAN is tailored to optimize physical IC layouts.

In Step 440, the GAN outputs a placement-optimal or modified embedding. This embedding reflects a layout that is optimized for key design metrics such as power, performance, area, and cost (PPAC). The model ensures that the generated layout adheres to these constraints.

Step 439 evaluates the loss function again, this time using the optimal placement derived from prior iterations. This step serves to validate the effectiveness of the embedding order and assess the model's predictive accuracy under refined layout conditions. If the loss function indicates suboptimal performance, the process may iterate further to adjust embeddings and improve layout fidelity. These rigorous extraction results, obtained from evaluating parasitic effects and layout characteristics can be used to tune the model parameters and enhance the loss function, thereby improving convergence and generalization. After one or more refinement cycles, a final layout is generated in Step 450, representing an improved transistor placement optimized for parasitic performance. Step 451 marks the end of the process, producing a layout ready for downstream tasks such as parasitic extraction, verification, and inspection.

Embodiments herein integrate recurrent GNNs with GANs to generate transistor embeddings and optimize layouts based on PPAC metrics. A novel data generation approach includes inverse modeling of Parasitic Extraction (PEX)R, C networks data and training on netlists with varied placement orders. Nodes may be defined using R, C network contact points, capturing resistance and capacitance values between them.

Optimization is guided by PPAC specifications and a ranking mechanism that selects layouts minimizing these values. The best-performing metal placements and minimized PPAC configurations serve as ground truth for GAN training. The recurrent GNN is trained on input mask data to form nodes and edges, improving the precision of node embeddings and enabling more effective layout generation.

Techniques herein can be implemented and stored on computer systems including corresponding data storage devices (tangible and non-transitory) for storing instructions, memory for handling instructions, one or more processors for executing instructions, and various inputs, interfaces, and sub-processing units for graphics, audio, and video, as well as signal generation and network connectivity. Techniques herein can include subsystems and subroutines for improved computing compared to conventional systems for electronic design automation.

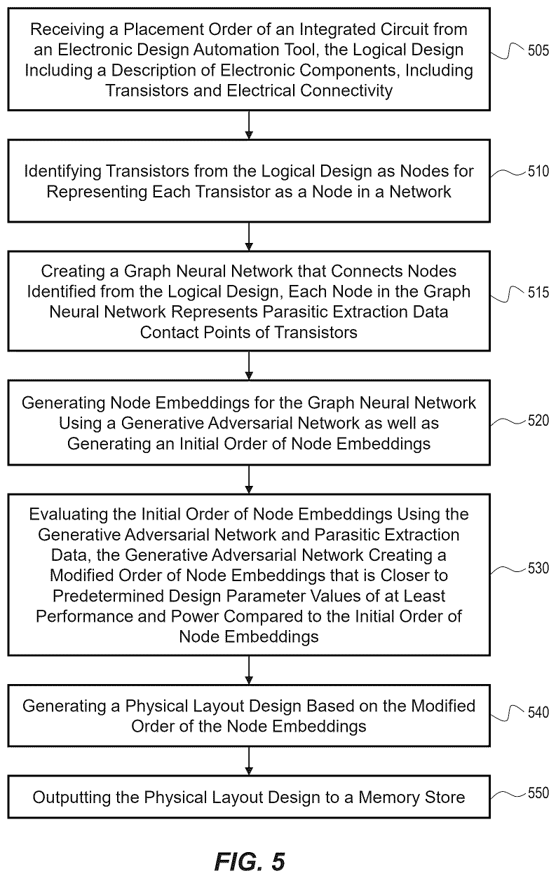

Referring now to FIG. 5, a flow chart illustrates one example embodiment herein. This includes a method and system for automating semiconductor design. In step 505, the system receives a netlist of an integrated circuit from an electronic design automation tool. The logical design can be a netlist, Graphic Design System (GDS) file such as GDSII, or other similar specification of a circuit design. The electronic design automation tool can include any software product or system for design and evaluation of integrated circuits, though typically for the netlist, for which an acceptable physical design needs to be created. The netlist includes a description of electronic components and connectivity including transistors.

In step 510 the system identifies transistors from the netlist as nodes for representing each transistor as a node in a network. In some embodiments, identifying transistors from the netlist as nodes includes modeling the transistors as nodes having a center point of each transistor being a location of respective nodes in a physical design that is used when performing parasitic extraction between given nodes. One tradeoff with such a representation is that parasitic extraction calculation will be somewhat less precise, but the benefit is being able to accelerate and optimize physical design creation by using a graph neural network as well as efficiently using the graph neural network. This technique can enable quickly identifying a relatively small pool of candidate physical layouts for further evaluation. In other words, a highly efficient method to automatically generate a physical layout that satisfies or exceeds design criteria.

In step 515 the system creates a graph neural network that connects nodes identified from the netlist. The graph neural network includes at least one million nodes or at least one million transistors. Each node in the graph neural network represents parasitic extraction data contact points of transistors from the netlist. This technique enables design automation by leveraging networks and relationship identifiers that would otherwise not be available. The graph neural network can be a recurrent graph neural network having a transformer architecture. This can be an architecture that converts nodes into tokens, or otherwise be used for ordering the node embeddings.

In step 520 the system generates node embeddings for the graph neural network of connected nodes using a generative adversarial network as well as generating an initial order of node embeddings. The generative adversarial network is beneficial to refine node embedding for improved physical layout generation. Generating the node embeddings can include modeling source, drain, and gate attributes of each transistor as a single embedding. The node embeddings can represent transistor contact points in which each contact point has a corresponding resistance and capacitance value as an edge weight that is treated as a single embedding within the graph neural network.

In step 530, the system evaluates the initial order of node embeddings using the generative adversarial network and parasitic extraction data. The generative adversarial network creates a modified order of node embeddings that is closer to predetermined design parameter values of at least performance and power compared to the initial order of node embeddings. Accordingly, the network improves an initial order of node embeddings after evaluation.

Iteration can further refine or optimize a modified layout. For example, the generative adversarial network can create a second modified order of node embeddings that is closer to predetermined design parameter values of at least performance and power compared to the modified order of node embeddings. The system generates a second physical layout design based on the second modified order of the node embeddings, and outputs the second physical layout design to a memory store. This process can be repeated a desired number of times.

In step 540, the system generates a physical layout design based on the modified order of the node embeddings. In step 550, the system can output the physical layout design to a memory store or other location for fabrication of the integrated circuit or further refining the layout design. This output can be, for example, a text format description of layout data (in a JSON file format) or another suitable layout.

Additional embodiments can include training the graph neural network using a machine learning model to generate parasitic extraction data and training the graph neural network on generated input mask data to form nodes and connected edges. Additional training data can be further obtained by making inverse calculations on parasitic extraction data. Moreover, metal placement identified as optimized after obtaining the modified order of node embeddings from two or more iterations can be used as rigorous TCAD simulation for training the generative adversarial network. In other embodiments, the predetermined design parameters values can further include area and cost, with metal placement in the physical layout design meeting the desired PPAC values.

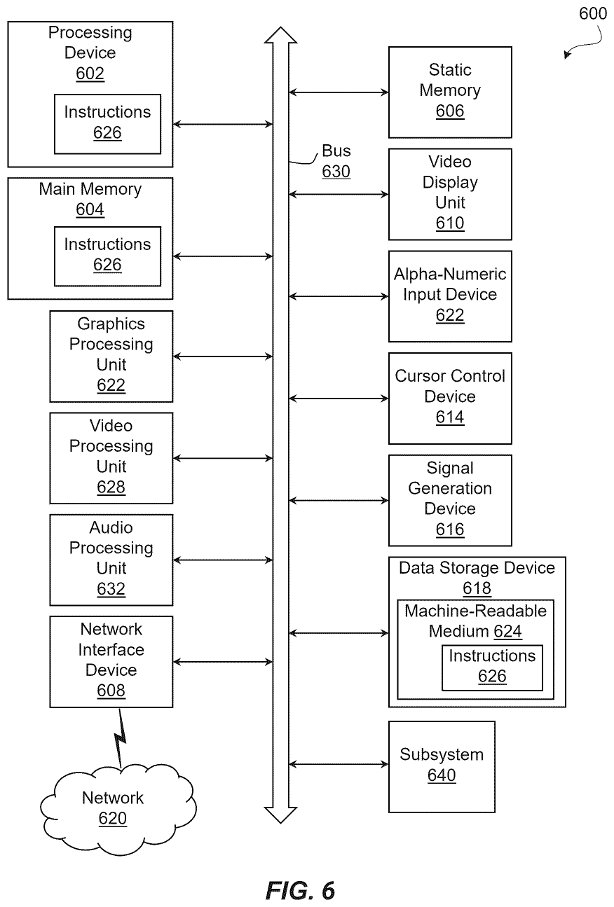

In other embodiments, the system can include receiving the netlist as an input of a modeling subsystem coupled to the electronic design automation tool. And then identifying transistors from the netlist, creating the graph neural network, generating the node embeddings, and modifying the initial order of the node embeddings can all be executed by a compression subsystem that includes one or more processors. A parasitic capacitance optimization processor coupled to the compression subsystem can be used to perform the parasitic extraction and generate the physical layout. These subsystems can be incorporated into Subsystem 640 of FIG. 6.

FIG. 6 depicts a representative diagram of an example computer system in which embodiments of the present disclosure may operate.

A storage subsystem of a computer system (such as computer system 600 of FIG. 6) may be used to store the programs and data structures that are used by some or all of the EDA products described herein, and products used for development of cells for the library and for physical and netlist that use the library.

FIG. 6 illustrates an example machine of a computer system 600 within which a set of instructions, for causing the machine to perform any one or more of the methodologies discussed herein, [including specific technique of this application in electronic design of an integrated circuit], may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The computer system 600 example includes a processing device 602, a main memory 604 (e.g., read-only memory (ROM), flash memory, dynamic random access memory (DRAM) such as synchronous DRAM (SDRAM), a static memory 606 (e.g., flash memory, static random access memory (SRAM), etc.), and a data storage device 618, which communicate with each other via a bus 630.

Processing device 602 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 may also be one or more special-purpose processing devices such as an application specific integrated circuit (ASIC), a field programmable gate array (FPGA), a digital signal processor (DSP), network processor, or the like. The processing device 602 may be configured to execute instructions 626 for performing the operations and steps described herein.

The computer system 600 may further include a network interface device 608 to communicate over the network 620. The computer system 600 also may include a video display unit 610 (e.g., a liquid crystal display (LCD) or a cathode ray tube (CRT)), an alphanumeric input device 612 (e.g., a keyboard), a cursor control device 614 (e.g., a mouse), a graphics processing unit 622, a signal generation device 616 (e.g., a speaker), graphics processing unit 622, video processing unit 628, and audio processing unit 632.

The data storage device 618 may include a machine-readable storage medium 624 (also known as a non-transitory computer-readable medium) on which is stored one or more sets of instructions 626 or software embodying any one or more of the methodologies or functions described herein. The instructions 626 may also reside, completely or at least partially, within the main memory 604 and/or within the processing device 602 during execution thereof by the computer system 600, the main memory 604 and the processing device 602 also constituting machine-readable storage media.

In some implementations, the instructions 626 include instructions to implement functionality corresponding to the present disclosure. While the machine-readable storage medium 624 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 602 to perform any one or more of the methodologies of the present disclosure. The term “machine-readable storage medium” shall accordingly be taken to include, but not be limited to, solid-state memories, optical media, and magnetic media.

Some portions of the preceding detailed description have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be noted, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

1. A method for automating semiconductor design, the method comprising:
receiving a placement order of a very large-scale integration (VLSI) integrated circuit from an electronic design automation tool, the placement order including a description of electronic components, including transistors and electrical connectivity;
identifying transistors from the placement order as nodes for representing each transistor as a node in a network;
creating, by a processing device, a graph neural network that connects nodes identified from the placement order, each node in the graph neural network represents parasitic extraction data contact points of transistors;
generating, by the processing device, node embeddings for the graph neural network using a generative adversarial network as well as generating an initial order of node embeddings;
evaluating, by the processing device, the initial order of node embeddings using the generative adversarial network and parasitic extraction data, the generative adversarial network creating a modified order of node embeddings that is closer to predetermined design parameter values of at least performance and power compared to the initial order of node embeddings;
generating, by the processing device, a physical layout design based on the modified order of the node embeddings; and
outputting, by the processing device, the physical layout design to a memory store.

2. The method of claim 1, wherein the node embeddings represent transistor contact points in which each contact point has a corresponding resistance and capacitance value as an edge weight that is treated as a single embedding within the graph neural network.

3. The method of claim 1, further comprising:
evaluating, by the processing device, the node embeddings of the modified order of node embeddings using the generative adversarial network and parasitic extraction data, the generative adversarial network creating a second modified order of node embeddings that is closer to predetermined design parameter values of at least performance and power compared to the modified order of node embeddings;
generating, by the processing device, a second physical layout design based on the second modified order of the node embeddings; and
outputting, by the processing device, the second physical layout design to a memory store.

4. The method of claim 1, further comprising training the graph neural network using a machine learning model to generate parasitic extraction data, and training the graph neural network on generated input mask data to form nodes and connected edges.

5. The method of claim 4, wherein additional training data is obtained by making inverse calculations on parasitic extraction data.

6. The method of claim 1, wherein the modified order of node embeddings results in metal placement in the physical layout design meeting the predetermined design parameter values of at least performance and power; and wherein the predetermined design parameters values further include area and cost.

7. The method of claim 1, wherein metal placement identified as optimized after obtaining the modified order of node embeddings from two or more iterations is used as ground truth for training the generative adversarial network.

8. A system comprising:
a memory storing instructions; and
a processing device, coupled with the memory and configured to execute the instructions, the instructions when executed cause the processing device to:
receive a netlist of an integrated circuit from an electronic design automation tool, the netlist including a description of electronic components, including transistors and electrical connectivity;
identify transistors from the netlist as nodes for representing each transistor as a node in a network;
create a graph neural network that connects nodes identified from the netlist, each node in the graph neural network represents parasitic extraction data contact points of transistors, the graph neural network including at least one million nodes;
generate node embeddings for the graph neural network using a generative adversarial network as well as generating an initial order of node embeddings;
evaluate the initial order of node embeddings using the generative adversarial network and parasitic extraction data, the generative adversarial network creating a modified order of node embeddings that is closer to predetermined design parameter values of at least performance and power compared to the initial order of node embeddings;
generate a physical layout design based on the modified order of the node embeddings; and
output the physical layout design to a memory store.

9. The system of claim 8, wherein the node embeddings represent transistor contact points in which each contact point has a corresponding resistance and capacitance value as an edge weight that is treated as a single embedding within the graph neural network.

10. The system of claim 8, wherein the instructions further cause the processing device to:
evaluate the node embeddings of the modified order of node embeddings using the generative adversarial network and parasitic extraction data, the generative adversarial network creating a second modified order of node embeddings that is closer to predetermined design parameter values of at least performance and power compared to the modified order of node embeddings;
generate a second physical layout design based on the second modified order of the node embeddings; and
output the second physical layout design to a memory store.

11. The system of claim 8, wherein the instructions further cause the processing device to:
train the graph neural network using a machine learning model to generate parasitic extraction data; and
train the graph neural network on generated input mask data to form nodes and connected edges.

12. The system of claim 11, wherein the instructions further cause the processing device to:
obtain additional training data by making inverse calculations on parasitic extraction data.

13. The system of claim 8, wherein the modified order of node embeddings results in metal placement in the physical layout design meeting the predetermined design parameter values of at least performance and power; and wherein the predetermined design parameters values further include area and cost.

14. The system of claim 8, wherein the instructions further cause the processing device to:
train the generative adversarial network using, as ground truth, metal placement identified as optimized after obtaining the modified order of node embeddings from two or more iterations.

15. A non-transitory computer readable medium comprising stored instructions, which when executed by a processing device, cause the processing device to:
receive a netlist of an integrated circuit from an electronic design automation tool, the netlist including a description of electronic components, including transistors and electrical connectivity;
identify transistors from the netlist as nodes for representing each transistor as a node in a network;
create a graph neural network that connects nodes identified from the netlist, each node in the graph neural network represents parasitic extraction data contact points of transistors, the graph neural network including at least one million nodes;
generate node embeddings for the graph neural network using a generative adversarial network as well as generating an initial order of node embeddings;
evaluate the initial order of node embeddings using the generative adversarial network and parasitic extraction data, the generative adversarial network creating a modified order of node embeddings that is closer to predetermined design parameter values of at least performance and power compared to the initial order of node embeddings;
generate a physical layout design based on the modified order of the node embeddings; and
output the physical layout design to a memory store.

16. The non-transitory computer readable medium of claim 15, wherein the node embeddings represent transistor contact points in which each contact point has a corresponding resistance and capacitance value as an edge weight that is treated as a single embedding within the graph neural network.

17. The non-transitory computer readable medium of claim 15, wherein the instructions further cause the processing device to:
evaluate the node embeddings of the modified order of node embeddings using the generative adversarial network and parasitic extraction data, the generative adversarial network creating a second modified order of node embeddings that is closer to predetermined design parameter values of at least performance and power compared to the modified order of node embeddings;
generate a second physical layout design based on the second modified order of the node embeddings; and
output the second physical layout design to a memory store.

18. The non-transitory computer readable medium of claim 15, wherein the instructions further cause the processing device to:
train the graph neural network using a machine learning model to generate parasitic extraction data; and
train the graph neural network on generated input mask data to form nodes and connected edges.

19. The non-transitory computer readable medium of claim 18, wherein the instructions further cause the processing device to:
obtain additional training data by making inverse calculations on parasitic extraction data.

20. The non-transitory computer readable medium of claim 15, wherein the modified order of node embeddings results in metal placement in the physical layout design meeting the predetermined design parameter values of at least performance and power, and wherein the predetermined design parameters values further include area and cost.
